(19) United States
(12) Patent Application Publication
(10) Pub. No.: US 2025/0006641 A1
(43) Pub. Date: Jan. 2, 2025

(54) SEMICONDUCTOR DEVICE

(71) Applicant: Samsung Electronics Co., Ltd., Suwon-si (KR)

(72) Inventors: Yoon Hee KANG, Suwon-si (KR); Jong Min BAEK, Suwon-si (KR); Eui Bok LEE, Suwon-si (KR)

(21) Appl. No.: 18/405,023

(22) Filed: Jan. 5, 2024

(30) Foreign Application Priority Data
Jun. 28, 2023 (KR) 10-2023-0083409

(51) Int. Cl. H01L 23/535; H01L 21/768; H01L 23/522; H01L 23/532

(52) U.S. Cl. CPC H01L 23/535; H01L 21/76805; H01L 21/76807; H01L 21/76835; H01L 21/76846; H01L 21/76877; H01L 21/76895; H01L 23/5226; H01L 23/53266; H01L 23/53295

(57) ABSTRACT

A semiconductor device including a first interlayer insulating layer on a substrate, a lower wiring pattern in the first interlayer insulating layer, a second interlayer insulating layer on the first interlayer insulating layer, a via filling layer filling a via trench in the second interlayer insulating layer, a third interlayer insulating layer contacting an upper surface of the second interlayer insulating layer, and an upper wiring pattern in an upper wiring trench formed on the via trench in the third interlayer insulating layer and contacting an upper surface of the via filling layer, the upper wiring pattern including a first upper wiring barrier layer on sidewalls of the upper wiring trench, a second upper wiring barrier layer on sidewalls of the first upper wiring barrier layer and the upper surface of the via filling layer, and an upper wiring filling layer on the second upper wiring barrier layer.

### CROSS-REFERENCE TO RELATED APPLICATION

This application claims priority under 35 U.S.C. § 119 from Korean Patent Application No. 10-2023-0083409, filed on Jun. 28, 2023, in the Korean Intellectual Property Office and all the benefits accruing therefrom under 35 U.S.C. § 119, the contents of which in its entirety are herein incorporated by reference.

### BACKGROUND

### Technical Field

The present disclosure relates to a semiconductor device.

### Description of the Related Art

Recently, as down-scaling of semiconductor devices has been rapidly progressed due to the development of electronic technology, high integration and low power of semiconductor chips are required. A gap between circuit components such as wiring is gradually reduced, resulting in a problem that resistance between wiring and vias is increased. In order to improve reliability of semiconductor devices, studies for solving the problem that resistance between wiring and vias is increased are ongoing.

### SUMMARY

An object of the present disclosure is to provide a semiconductor device comprising a wiring pattern and a via filling layer, which are fabricated by a dual damascene, in which a process margin is improved, resistance of the via filling layer is reduced, and a fabricating process is simplified.

According to some embodiments of the present disclosure, there is provided a semiconductor device, comprising a substrate, a first interlayer insulating layer disposed on the substrate, a lower wiring pattern disposed in the first interlayer insulating layer, a second interlayer insulating layer disposed on the first interlayer insulating layer, a via trench formed in the second interlayer insulating layer, the via trench extending to an upper surface of the lower wiring pattern, a via filling layer filling the via trench, a third interlayer insulating layer in contact with an upper surface of the second interlayer insulating layer on the second interlayer insulating layer, the third interlayer insulating layer including a material different from a material included in the second interlayer insulating layer, an upper wiring trench formed on the via trench in the third interlayer insulating layer, and an upper wiring pattern in contact with an upper surface of the via filling layer, the upper wiring pattern filling the upper wiring trench, the upper wiring pattern including a first upper wiring barrier layer disposed on sidewalls of the upper wiring trench, a second upper wiring barrier layer disposed on sidewalls of the first upper wiring barrier layer and the upper surface of the via filling layer, and an upper wiring filling layer disposed on the second upper wiring barrier layer, wherein the via filling layer and the first upper wiring barrier layer include the same material.

According to some embodiments of the present disclosure, there is provided a semiconductor device, comprising a substrate, a first interlayer insulating layer disposed on the substrate, a via trench formed in the first interlayer insulating layer, a via filling layer filling the via trench, a second interlayer insulating layer in contact with an upper surface of the first interlayer insulating layer on the first interlayer insulating layer, the second interlayer insulating layer including a material different from a material included in the first interlayer insulating layer, an upper wiring trench formed on the via trench in the second interlayer insulating layer, and an upper wiring pattern in contact with an upper surface of the via filling layer, the upper wiring pattern filling the upper wiring trench, the upper wiring pattern including a first upper wiring barrier layer disposed on sidewalls of the upper wiring trench, a second upper wiring barrier layer disposed on sidewalls of the first upper wiring barrier layer and the upper surface of the via filling layer, an upper wiring filling layer disposed on the second upper wiring barrier layer, and an interface layer disposed between the first upper wiring barrier layer and the second upper wiring barrier layer and between the upper surface of the via filling layer and the second upper wiring barrier layer, wherein the via filling layer and the first upper wiring barrier layer include the same material.

According to some embodiments of the present disclosure, there is provided a semiconductor device, comprising a substrate, a first interlayer insulating layer disposed on the substrate, a lower wiring pattern disposed in the first interlayer insulating layer, a second interlayer insulating layer disposed on the first interlayer insulating layer, the second interlayer insulating layer including tetraethyl orthosilicate (TEOS), a via trench formed in the second interlayer insulating layer, the via trench extending to an upper surface of the lower wiring pattern, a via filling layer filling the via trench, a third interlayer insulating layer in contact with an upper surface of the second interlayer insulating layer on the second interlayer insulating layer, the third interlayer insulating layer including a low dielectric constant material different from tetraethyl orthosilicate (TEOS), an upper wiring trench formed on the via trench in the third interlayer insulating layer, and an upper wiring pattern in contact with an upper surface of the via filling layer, the upper wiring pattern filling the upper wiring trench, the upper wiring pattern including a first upper wiring barrier layer disposed on sidewalls of the upper wiring trench, a second upper wiring barrier layer disposed on sidewalls of the first upper wiring barrier layer and the upper surface of the via filling layer, an upper wiring filling layer disposed on the second upper wiring barrier layer, and an interface layer disposed between the first upper wiring barrier layer and the second upper wiring barrier layer and between the upper surface of the via filling layer and the second upper wiring barrier layer, wherein each of the via filling layer and the first upper wiring barrier layer includes molybdenum (Mo), wherein at least a portion of the second upper wiring barrier layer is in contact with the upper surface of the second interlayer insulating layer in the upper wiring trench, and wherein at least a portion of the upper surface of the via filling layer is formed to be higher than the upper surface of the second interlayer insulating layer.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a semiconductor device according to example embodiments of the present disclosure;

FIG. 2 is an enlarged view illustrating a region R1 of FIG. 1;

FIG. 3 is an enlarged view illustrating a region R2 of FIG. 1;

FIGS. 4 to 10 are views illustrating intermediate steps to describe manufacturing a semiconductor device according to example embodiments of the present disclosure;

FIG. 11 is a view illustrating a semiconductor device according to example other embodiments of the present disclosure;

FIG. 12 is an enlarged view illustrating a region R3 of FIG. 11;

FIG. 13 is a view illustrating a semiconductor device according to example embodiments of the present disclosure;

FIG. 14 is an enlarged view illustrating a region R4 of FIG. 13;

FIG. 15 is a view illustrating a semiconductor device according to example embodiments of the present disclosure; and

FIG. 16 is an enlarged view illustrating a region R5 of FIG. 15.

### DETAILED DESCRIPTION OF THE DISCLOSURE

Terms such as “same,” “equal,” “planar,” or “coplanar,” as used herein, encompass near identicality including variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Like reference characters refer to like elements throughout. It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

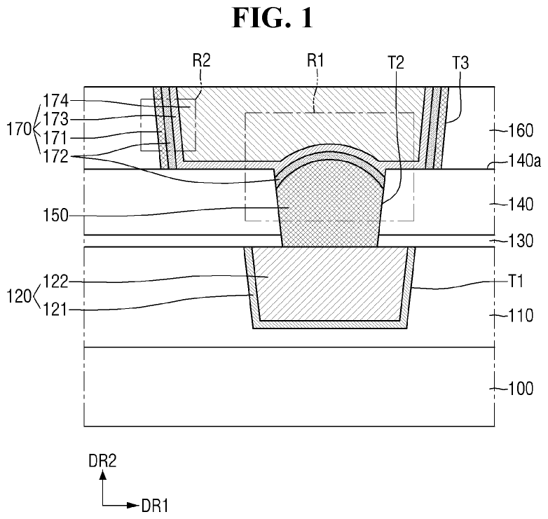

Hereinafter, a semiconductor device according to example embodiments of the present disclosure will be described with reference to FIGS. 1 to 3.

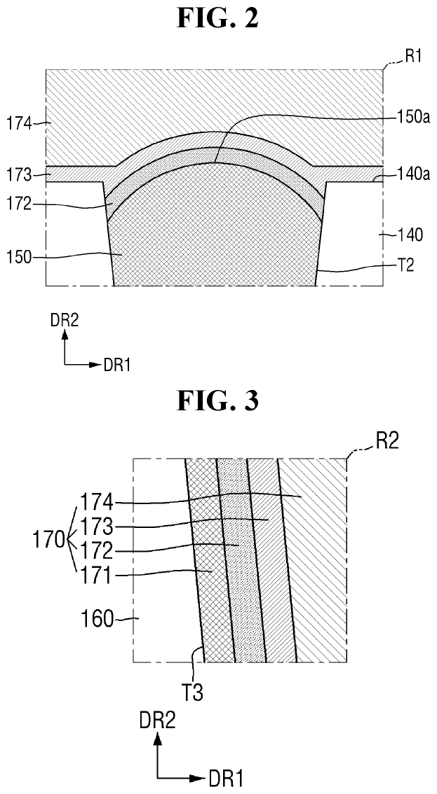

FIG. 1 is a view illustrating a semiconductor device according to example embodiments of the present disclosure. FIG. 2 is an enlarged view illustrating a region R1 of FIG. 1. FIG. 3 is an enlarged view illustrating a region R2 of FIG. 1.

Referring to FIGS. 1 to 3, the semiconductor device according to some embodiments of the present disclosure includes a substrate 100, a first interlayer insulating layer 110, a lower wiring pattern 120, an etch stop layer 130, a second interlayer insulating layer 140, a via filling layer 150, a third interlayer insulating layer 160, and an upper wiring pattern 170.

The substrate 100 may have a structure in which a base substrate and an epitaxial layer are stacked, but the present disclosure is not limited thereto. The substrate 100 may be a silicon substrate, a gallium arsenide substrate, a silicon germanium substrate, a ceramic substrate, a quartz substrate, or a glass substrate for a display, or may be a semiconductor on insulator (SOI) substrate.

In addition, although not shown, the substrate 100 may include a conductive pattern. The conductive pattern may be a metal wiring, a contact or the like, a gate electrode of a transistor, a source/drain of a transistor, a diode, or the like, but the present disclosure is not limited thereto.

Hereinafter, a horizontal direction DR1 may be defined as a direction parallel with an upper surface of the substrate 100. A vertical direction DR2 may be defined as a direction perpendicular to the horizontal direction DR1. That is, the vertical direction DR2 may be defined as a direction perpendicular to the upper surface of the substrate 100.

The first interlayer insulating layer 110 may be disposed on the upper surface of the substrate 100. The first interlayer insulating layer 110 may be formed of or include at least one of, for example, silicon oxide, silicon nitride, silicon oxynitride or a low dielectric constant material. The low dielectric constant material may be formed of or include Tetraethyl orthosilicate (TEOS), Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica, or their combinations, but the present disclosure is not limited thereto.

A lower wiring trench T1 may be formed in the first interlayer insulating layer 110. The lower wiring trench T1 may be formed to be recessed from an upper surface of the first interlayer insulating layer 110 toward the inside of the first interlayer insulating layer 110. For example, sidewalls and a bottom surface of the lower wiring trench T1 may be defined by the first interlayer insulating layer 110. For example, a width of the lower wiring trench T1 in the horizontal direction DR1 may be continuously reduced as the lower wiring trench T1 becomes adjacent to the upper surface of the substrate 100.

The lower wiring pattern 120 may be disposed in the lower wiring trench T1. For example, the lower wiring pattern 120 may be disposed in the first interlayer insulating layer 110. In example embodiments, a width of the lower wiring pattern 120 in the horizontal direction DR1 may be continuously reduced as the lower wiring pattern 120 becomes adjacent to the upper surface of the substrate 100. For example, an upper surface of the lower wiring pattern 120 may be exposed on the upper surface of the first interlayer insulating layer 110. The lower wiring pattern 120 may include a lower wiring barrier layer 121 and a lower wiring filling layer 122.

The lower wiring barrier layer 121 may be disposed along the sidewalls and the bottom surface of the lower wiring trench T1. For example, the lower wiring barrier layer 121 may be formed to be conformal. The lower wiring barrier layer 121 may contact the first interlayer insulating layer 110. For example, an uppermost surface of the lower wiring barrier layer 121 may be exposed on the upper surface of the first interlayer insulating layer 110. The uppermost surface of the lower wiring barrier layer 121 may be coplanar with the upper surface of the first interlayer insulating layer 110. The lower wiring barrier layer 121 may be formed of or include one of, for example, titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN) and their combination, but the present disclosure is not limited thereto.

The lower wiring filling layer 122 may be disposed on the lower wiring barrier layer 121 inside the lower wiring trench T1. The lower wiring filling layer 122 may contact the lower wiring barrier layer 121. The lower wiring filling layer 122 may fill the inside of the lower wiring trench T1 on the lower wiring barrier layer 121. For example, an upper surface of the lower wiring filling layer 122 may be exposed on the upper surface of the first interlayer insulating layer 110. The upper surface of the lower wiring filling layer 122 may be coplanar with the upper surface of the first interlayer insulating layer 110. The lower wiring filling layer 122 may be formed of or include at least one of, for example, copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), or rhodium (Rh), but the present disclosure is not limited thereto.

The etch stop layer 130 may be disposed on the upper surface of the first interlayer insulating layer 110 and the upper surface of the lower wiring pattern 120. The etch stop layer 130 may contact the upper surfaces of the first interlayer insulating layer 110 and the lower wiring pattern 120. For example, the etch stop layer 130 may be formed to be conformal. Although the etch stop layer 130 is shown as a single layer in FIG. 1, the present disclosure is not limited thereto. In some other embodiments, the etch stop layer 130 may be formed of multiple layers. The etch stop layer 130 may be formed of or include at least one of, for example, aluminum oxide, aluminum nitride, hafnium oxide, zirconium oxide, silicon oxide, silicon nitride, silicon oxynitride or a low dielectric constant material.

The second interlayer insulating layer 140 may be disposed on the etch stop layer 130. The second interlayer insulating layer 140 may contact an upper surface of the etch stop layer 130. The second interlayer insulating layer 140 may be formed of or include, for example, tetraethyl orthosilicate (TEOS). A via trench T2 may be formed in the second interlayer insulating layer 140. For example, the via trench T2 may pass through the etch stop layer 130 and the second interlayer insulating layer 140 in the vertical direction DR2. The via trench T2 may be extended to the upper surface of the lower wiring pattern 120. For example, a width of the via trench T2 in the horizontal direction DR1 may be continuously reduced as the via trench T2 approaches the upper surface of the lower wiring pattern 120. For example, a width of a bottom surface of the via trench T2 in the horizontal direction DR1 may be smaller than that of the upper surface of the lower wiring pattern 120 in the horizontal direction DR1.

The via filling layer 150 may be disposed in the via trench T2. For example, the via filling layer 150 may fill the via trench T2. A lower surface of the via filling layer 150 may be in contact with the upper surface of the lower wiring pattern 120 inside the via trench T2. Sidewalls of the via filling layer 150 may be in contact with sidewalls of the second interlayer insulating layer 140 inside the via trench T2 and sidewalls of the etch stop layer 130.

For example, an upper surface 150a of the via filling layer 150 may be formed to be convex in the vertical direction DR2. For example, an uppermost surface of the via filling layer 150, which is a middle portion of the upper surface 150a of the via filling layer 150, may be formed to be higher than an upper surface 140a of the second interlayer insulating layer 140. For example, a portion of the upper surface 150a of the via filling layer 150, which is adjacent to sidewalls of the via trench T2, may be formed to be lower than the upper surface 140a of the second interlayer insulating layer 140. That is, at least a portion of the upper surface 150a of the via filling layer 150 may be formed to be higher than the upper surface 140a of the second interlayer insulating layer 140. At least another portion of the upper surface 150a of the via filling layer 150 may be formed to be lower than the upper surface 140a of the second interlayer insulating layer 140. The via filling layer 150 may be formed of or include any one of, for example, molybdenum (Mo) and ruthenium (Ru). For example, the via filling layer 150 may be formed of a single layer.

The third interlayer insulating layer 160 may be disposed on the upper surface 140a of the second interlayer insulating layer 140. For example, the third interlayer insulating layer 160 may be in contact with the upper surface 140a of the second interlayer insulating layer 140. The third interlayer insulating layer 160 may be formed of or include a material different from that of the second interlayer insulating layer 140. For example, the third interlayer insulating layer 160 may be formed of or include a material having higher deposition selectivity with respect to metal than the second interlayer insulating layer 140. Therefore, a first upper wiring barrier layer 171, which will be described later, may be selectively formed on a surface of the third interlayer insulating layer 160 without being formed on the upper surface 140a of the second interlayer insulating layer 140.

The third interlayer insulating layer 160 may be formed of or include, for example, silicon oxide, silicon nitride, and silicon oxynitride. The third interlayer insulating layer 160 may include, for example, a low dielectric constant material different from tetraethyl orthosilicate (TEOS). For example, the second interlayer insulating layer 140 may be formed of or include tetraethyl orthosilicate (TEOS), and the third interlayer insulating layer 160 may be formed of or include a low dielectric constant material different from tetraethyl orthosilicate (TEOS).

An upper wiring trench T3 may be formed inside the third interlayer insulating layer 160. The upper wiring trench T3 may be formed on the via trench T2. That is, the upper wiring trench T3 may overlap the via trench T2 in the vertical direction DR2. A bottom surface of the upper wiring trench T3 may be defined by the upper surface 140a of the second interlayer insulating layer 140. Sidewalls of the upper wiring trench T3 may be defined by those of the third interlayer insulating layer 160. For example, as the upper wiring trench T3 becomes adjacent to the upper surface 140a of the second interlayer insulating layer 140, a width of the upper wiring trench T3 in the horizontal direction DR1 may be continuously reduced. For example, a width of the bottom surface of the upper wiring trench T3 in the horizontal direction DR1 may be greater than that of the upper surface of the via filling layer 150 in the horizontal direction DR1.

The upper wiring pattern 170 may be disposed in the upper wiring trench T3. For example, the upper wiring pattern 170 may fill the upper wiring trench T3. The upper wiring pattern 170 may be in contact with the upper surface 150a of the via filling layer 150. For example, at least a portion of the upper wiring pattern 170 may be disposed in the via trench T2. For example, a width of the upper wiring pattern 170 in the horizontal direction DR1 may be continuously reduced as the upper wiring pattern 170 becomes adjacent to the upper surface 140a of the second interlayer insulating layer 140. For example, the upper wiring pattern 170 may include a first upper wiring barrier layer 171, an interface layer 172. a second upper wiring barrier layer 173 and an upper wiring filling layer 174.

The first upper wiring barrier layer 171 may be disposed on the sidewalls of the upper wiring trench T3. The first upper wiring barrier layer 171 may be in contact with the sidewalls of the third interlayer insulating layer 160. A lower surface of the first upper wiring barrier layer 171 may contact the upper the upper surface 140a of the second interlayer insulating layer 140. An upper surface of the first upper wiring barrier layer 171 may be coplanar with an upper surface of the third interlayer insulating layer 160. For example, the first upper wiring barrier layer 171 may be extended from the upper surface 140a of the second interlayer insulating layer 140 to the upper surface of the third interlayer insulating layer 160 along the sidewalls of the upper wiring trench T3. For example, the first upper wiring barrier layer 171 may be formed to be conformal, but the present disclosure is not limited thereto.

For example, the first upper wiring barrier layer 171 is not disposed between the upper surface 140a of the second interlayer insulating layer 140 and the upper wiring filling layer 174 that will be described later. In addition, the first upper wiring barrier layer 171 is not disposed between the upper surface 150a of the via filling layer 150 and the upper wiring filling layer 174 that will be described later.

The first upper wiring barrier layer 171 may include the same material as that of the via filling layer 150. The first upper wiring barrier layer 171 may be formed of or include any one of molybdenum (Mo) and ruthenium (Ru). In some embodiments, each of the first upper wiring barrier layer 171 and the via filling layer 150 may be formed of or include molybdenum (Mo). In some other embodiments, each of the first upper wiring barrier layer 171 and the via filling layer 150 may be formed of or include ruthenium (Ru). For example, the first upper wiring barrier layer 171 and the via filling layer 150 may be formed through the same fabricating process, and their fabricating process will be described later in detail.

The second upper wiring barrier layer 173 may be disposed on sidewalls of the first upper wiring barrier layer 171, the upper surface 140a of the second interlayer insulating layer 140, and the upper surface 150a of the via filling layer 150 inside the upper wiring trench T3. An upper surface of the second upper wiring barrier layer 173 may be coplanar with an upper surface of the third interlayer insulating layer 160. For example, the second upper wiring barrier layer 173 may be spaced apart from the first upper wiring barrier layer 171 in the horizontal direction DR1. The second upper wiring barrier layer 173 may be spaced apart from the upper surface 150a of the via filling layer 150 in the vertical direction DR2. For example, the second upper wiring barrier layer 173 may be in contact with the upper surface 140a of the second interlayer insulating layer 140 inside the upper wiring trench T3.

For example, at least a portion of the second upper wiring barrier layer 173 may be disposed inside the via trench T2. For example, at least a portion of the second upper wiring barrier layer 173 may be in contact with the sidewalls of the second interlayer insulating layer 140 inside the via trench T2. For example, the second upper wiring barrier layer 173 may be formed to be conformal, but the present disclosure is not limited thereto. The second upper wiring barrier layer 173 may be formed of or include one of, for example, titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN) and their combination.

The interface layer 172 may be disposed between the first upper wiring barrier layer 171 and the second upper wiring barrier layer 173. The interface layer 172 disposed between the first upper wiring barrier layer 171 and the second upper wiring barrier layer 173 may be extended from the upper surface 140a of the second interlayer insulating layer 140 to the upper surface of the third interlayer insulating layer 160. The interface layer 172 may be in contact with each of the first upper wiring barrier layer 171 and the second upper wiring barrier layer 173.

The interface layer 172 may be disposed between the upper surface 150a of the via filling layer 150 and the second upper wiring barrier layer 173. For example, at least a portion of the interface layer 172 disposed between the upper surface 150a of the via filling layer 150 and the second upper wiring barrier layer 173 may be disposed inside the via trench T2. At least a portion of the interface layer 172 in the via trench T2 may be in contact with the sidewalls of the second interlayer insulating layer 140. Although the interface layer 172 is shown in FIGS. 1 to 3 as being conformal, this is for convenience of description and the present disclosure is not limited thereto.

The interface layer 172 may include, for example, a metal nitride. For example, when the first upper wiring barrier layer 171 includes molybdenum (Mo), the interface layer 172 may be formed of or include molybdenum nitride (MoN). For example, when the first upper wiring barrier layer 171 includes ruthenium (Ru), the interface layer 172 may be formed of or include ruthenium nitride (RuN).

The upper wiring filling layer 174 may be disposed on the second upper wiring barrier layer 173 inside the upper wiring trench T3. The upper wiring filling layer 174 may fill the inside of the upper wiring trench T3 on the second upper wiring barrier layer 173. The upper wiring filling layer 174 may contact the second upper wiring barrier layer 173. For example, an upper surface of the upper wiring filling layer 174 may be exposed on the upper surface of the third interlayer insulating layer 160.

The upper wiring filling layer 174 may be formed of or include at least one of, for example, copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir) or rhodium (Rh), but the present disclosure is not limited thereto.

Hereinafter, a method for fabricating a semiconductor device according to example embodiments of the present disclosure will be described with reference to FIGS. 1 and 4 to 10.

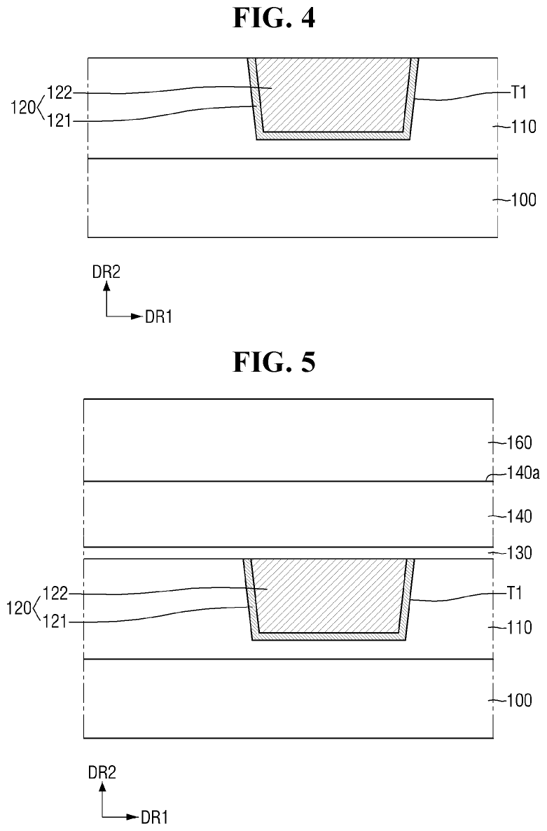

FIGS. 4 to 10 are views illustrating intermediate steps to describe a semiconductor device according to some embodiments of the present disclosure.

Referring to FIG. 4, the first interlayer insulating layer 110 may be formed on the upper surface of the substrate 100. The lower wiring trench T1 may be formed inside the first interlayer insulating layer 110. The lower wiring trench T1 may be formed to be recessed from the upper surface of the first interlayer insulating layer 110 toward the inside of the first interlayer insulating layer 110. The lower wiring pattern 120 including the lower wiring barrier layer 121 and the lower wiring filling layer 122 may be formed in the lower wiring trench T1.

For example, the lower wiring barrier layer 121 may be formed on the upper surface of the first interlayer insulating layer 110 and the sidewalls and the bottom surface of the lower wiring trench T1. The lower wiring filling layer 122 may be formed on the lower wiring barrier layer 121 inside the lower wiring trench T1 and on the upper surface of the first interlayer insulating layer 110. Then, the upper surface of the first interlayer insulating layer 110 may be exposed by a planarization process.

Referring to FIG. 5, the etch stop layer 130, the second interlayer insulating layer 140 and the third interlayer insulating layer 160 may be sequentially formed on each of the upper surface of the first interlayer insulating layer 110 and the upper surface of the lower wiring pattern 120. The third interlayer insulating layer 160 may include a material different from that of the second interlayer insulating layer 140. For example, the third interlayer insulating layer 160 may include a material having higher deposition selectivity with respect to metal than the second interlayer insulating layer 140. For example, the second interlayer insulating layer 140 may be formed of or include tetraethyl orthosilicate (TEOS), and the third interlayer insulating layer 160 may be formed of or include a low dielectric constant material different from tetraethyl orthosilicate (TEOS).

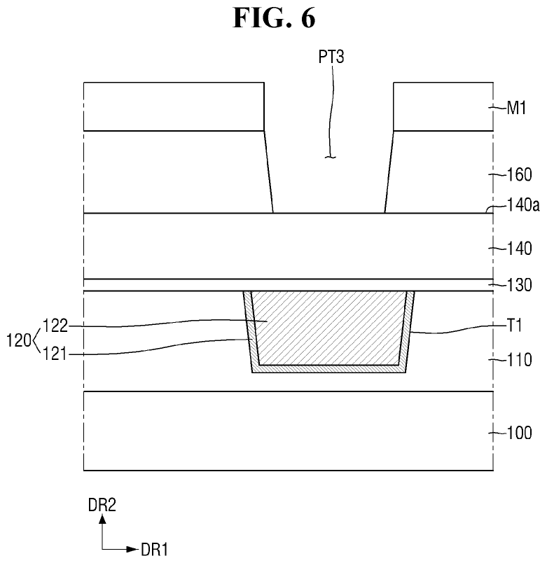

Referring to FIG. 6, a first mask pattern M1 may be formed on the upper surface of the third interlayer insulating layer 160. The third interlayer insulating layer 160 may be etched using the first mask pattern M1 as an etching mask. A pre-upper wiring trench PT3 may be formed inside the third interlayer insulating layer 160 through such an etching process. The pre-upper wiring trench PT3 may be formed to be recessed from the upper surface of the third interlayer insulating layer 160 toward the inside of the third interlayer insulating layer 160. The upper surface 140a of the second interlayer insulating layer 140 may be exposed by the pre-upper wiring trench PT3.

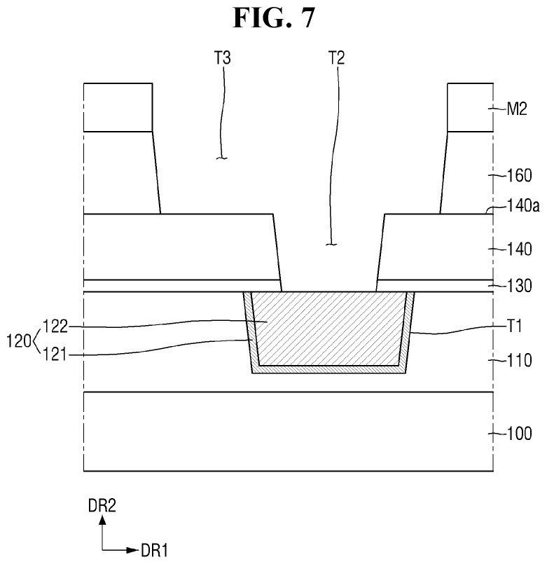

Referring to FIG. 7, the first mask pattern M1 may be removed. Then, a second mask pattern M2 may be formed on the upper surface of the third interlayer insulating layer 160. The third interlayer insulating layer 160, the second interlayer insulating layer 140 and the etch stop layer 130 may be etched using the second mask pattern M2 as an etching mask.

For example, a trench formed by etching the second interlayer insulating layer 140 and the etch stop layer 130 may be defined as the via trench T2. The via trench T2 may be formed to be recessed from the upper surface 140a of the second interlayer insulating layer 140 toward the inside of the second interlayer insulating layer 140. The upper surface of the lower wiring pattern 120 may be exposed by the via trench T2.

In addition, a trench formed by etching the third interlayer insulating layer 160 may be defined as the upper wiring trench T3. The upper wiring trench T3 may be formed to be recessed from the upper surface of the third interlayer insulating layer 160 toward the inside of the third interlayer insulating layer 160. A portion of the upper surface 140a of the second interlayer insulating layer 140 and the via trench T2 may be exposed by the third interlayer insulating layer 160. For example, a width of the upper wiring trench T3 in the horizontal direction DR1 may be greater than that of the via trench T2 in the horizontal direction DR1.

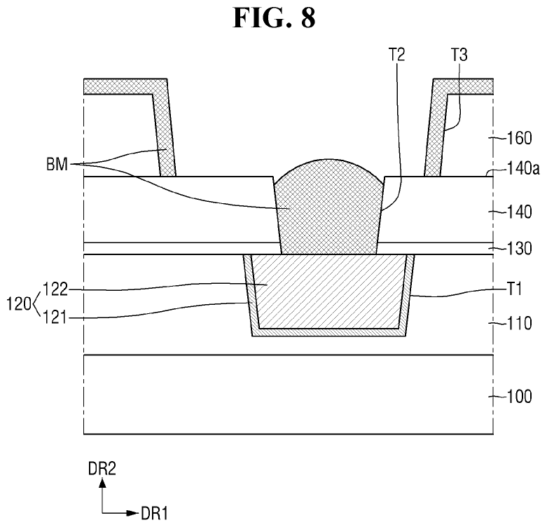

Referring to FIG. 8, after the second mask pattern (e.g., second mask pattern M2 in FIG. 7) is removed, a barrier material layer BM may be formed inside the via trench T2. The barrier material layer BM may fill the via trench T2. Also, the barrier material layer BM may be also formed on the sidewalls and the upper surface of the upper wiring trench T3. For example, the barrier material layer BM formed on the sidewalls and the upper surface of the upper wiring trench T3 may be formed to be conformal, but the present disclosure is not limited thereto.

Although FIG. 8 shows that the barrier material layer BM is formed after the second mask pattern (e.g., second mask pattern M2 of FIG. 7) is removed, but the present disclosure is not limited thereto. In some other embodiments, the second mask pattern (e.g., second mask pattern M2 of FIG. 7) is not removed, and the barrier material layer BM may be formed on the sidewalls and the upper surface of the second mask pattern (e.g., second mask pattern M2 of FIG. 7) and the sidewalls of the upper wiring trench T3 and inside the via trench T2.

The barrier material layer BM may be formed by an atomic layer deposition (ALD) process. For example, the barrier material layer BM may be selectively deposited on the lower wiring filling layer 122, which includes metal, to fill the via trench T2. Also, while the barrier material layer BM is selectively deposited on the lower wiring filling layer 122, the barrier material layer BM may be selectively deposited on the exposed sidewalls and upper surface of the third interlayer insulating layer 160.

However, the barrier material layer BM is not deposited on the exposed upper surface of the second interlayer insulating layer 140. Since the third interlayer insulating layer 160 includes a material having higher deposition selectivity with respect to metal than the second interlayer insulating layer 140, the barrier material layer BM may be selectively deposited on the exposed third interlayer insulating layer 160 without being deposited on the exposed surface of the second interlayer insulating layer 140.

The barrier material layer BM formed inside the via trench T2 and the barrier material layer BM formed on the sidewalls and the upper surface of the third interlayer insulating layer 160 may be formed through the same fabricating process. That is, the barrier material layer BM formed inside the via trench T2 and the barrier material layer BM formed on the sidewalls and the upper surface of the third interlayer insulating layer 160 may include the same material. The barrier material layer BM may be formed of or include any one of, for example, molybdenum (Mo) and ruthenium (Ru).

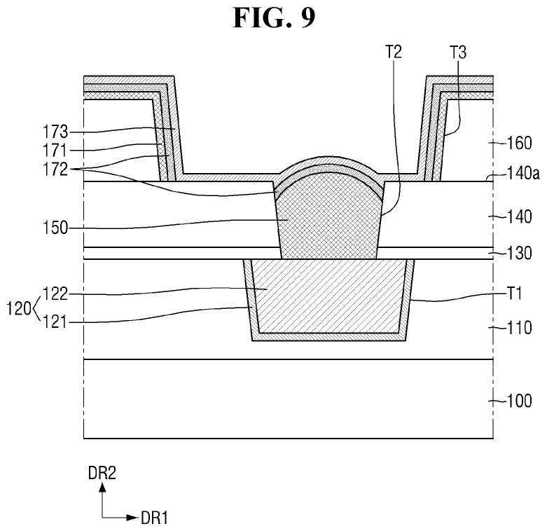

Referring to FIG. 9, the second upper wiring barrier layer 173 may be formed on the barrier material layer (BM of FIG. 8). The second upper wiring barrier layer 173 may be also formed on the upper surface 140a of the second interlayer insulating layer 140 inside the upper wiring trench T3. At least a portion of the second upper wiring barrier layer 173 may be also formed on the exposed sidewalls of the second interlayer insulating layer 140 inside the via trench T2.

While the second upper wiring barrier layer 173 is formed, a portion of the barrier material layer (e.g., barrier material layer BM of FIG. 8), which is in contact with the second upper wiring barrier layer 173, may be nitrified to form the interface layer 172. After the second upper wiring barrier layer 173 is formed, the barrier material layer (e.g., barrier material layer BM of FIG. 8), which remains without being nitrified, may be defined as the first upper wiring barrier layer 171 and the via filling layer 150. For example, after the second upper wiring barrier layer 173 is formed, the barrier material layer (e.g., barrier material layer BM of FIG. 8) remaining without being nitrified on the sidewalls of the upper wiring trench T3 may be defined as the first upper wiring barrier layer 171. After the second upper wiring barrier layer 173 is formed, the barrier material layer (e.g., barrier material layer BM of FIG. 8) remaining without being nitrified in the via trench T2 may be defined as the via filling layer 150.

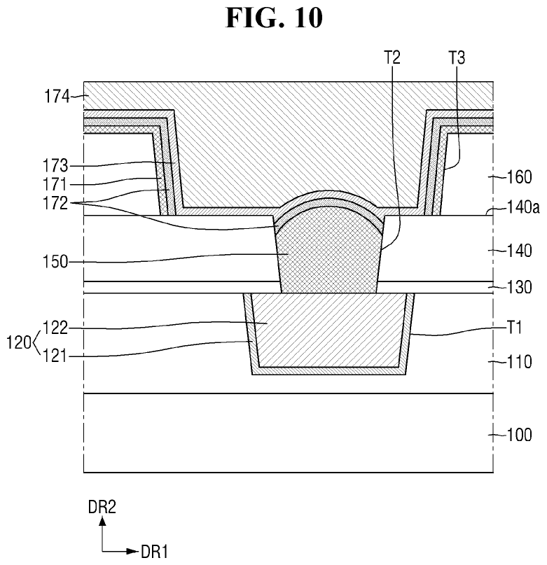

Referring to FIG. 10, the upper wiring filling layer 174 may be formed on the second upper wiring barrier layer 173. The upper wiring filling layer 174 may completely fill the inside of the upper wiring trench T3 on the second upper wiring barrier layer 173.

Referring to FIG. 1, a planarization process may be performed to expose the upper surface of the third interlayer insulating layer 160. Through this fabricating process, the semiconductor device shown in FIG. 1 may be fabricated.

In the semiconductor device according to example embodiments of the present disclosure, the via filling layer 150 formed in the via trench T2 and the first upper wiring barrier layer 171 formed on the sidewalls of the upper wiring trench T3 may be formed through the same fabricating process. The third interlayer insulating layer 160 in which the upper wiring trench T3 is formed may include a material having higher deposition selectivity with respect to metal than the second interlayer insulating layer 140 in which the via trench T2 is formed. Therefore, the first upper wiring barrier layer 171 may be selectively formed on the sidewalls of the upper wiring trench T3 and in the via trench T2.

In the semiconductor device according to example embodiments of the present disclosure, since the via filling layer 150 is formed in the via trench T2 before the upper wiring pattern 170 is formed in the upper wiring trench T3, a process margin may be improved, and resistance of the via filling layer 150 may be reduced. Also, in the semiconductor device according to example embodiments of the present disclosure, the third interlayer insulating layer 160 and the second interlayer insulating layer 140 may be formed to include their respective materials different from each other, so that no etch stop layer is disposed between the third interlayer insulating layer 160 and the second interlayer insulating layer 140, and the via filling layer 150 and the upper wiring pattern 170 are formed through a dual damascene process, whereby the fabricating process may be simplified.

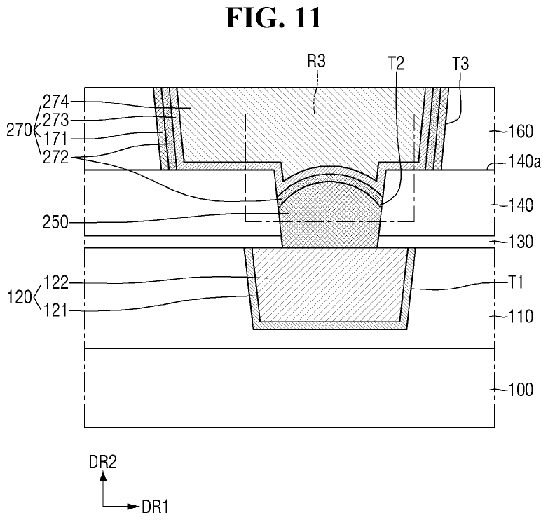

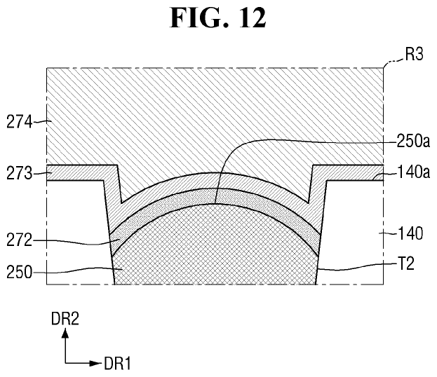

Hereinafter, a semiconductor device according to some other example embodiments of the present disclosure will be described with reference to FIGS. 11 and 12. The following description will be based on differences from the semiconductor device shown in FIGS. 1 to 3.

FIG. 11 is a view illustrating a semiconductor device according to some other example embodiments of the present disclosure. FIG. 12 is an enlarged view illustrating a region R3 of FIG. 11.

Referring to FIGS. 11 and 12, in the semiconductor device according to some other embodiments of the present disclosure, an upper surface 250a of a via filling layer 250 may be formed to be entirely lower than the upper surface 140a of the second interlayer insulating layer 140.

For example, an upper wiring pattern 270 may include a first upper wiring barrier layer 171, an interface layer 272, a second upper wiring barrier layer 273, and an upper wiring filling layer 274. For example, the interface layer 272 disposed between the upper surface 250a of the via filling layer 250 and the second upper wiring barrier layer 273 may be disposed inside the via trench T2. For example, at least a portion of the second upper wiring barrier layer 273 may be disposed in the via trench T2. For example, at least a portion of the upper wiring filling layer 274 may be disposed in the via trench T2.

The via filling layer 250, the interface layer 272, the second upper wiring barrier layer 273, and the upper wiring filling layer 274 may be formed of or include the same materials as those of the via filling layer 150, the interface layer 172, the second upper wiring barrier layer 173, and the upper wiring filling layer 174, respectively.

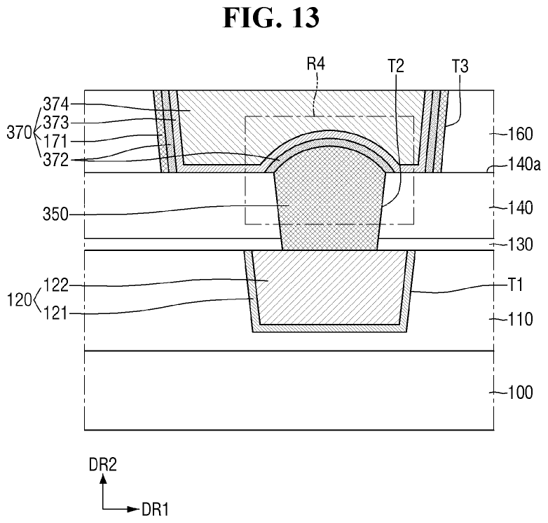

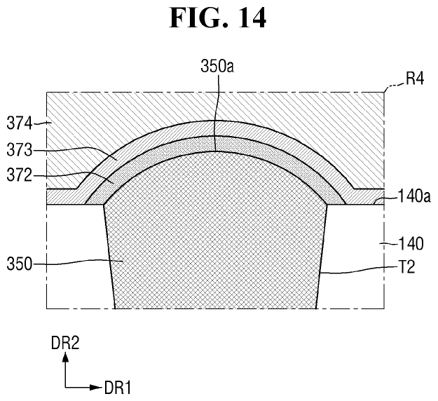

Hereinafter, a semiconductor device according to some other example embodiments of the present disclosure will be described with reference to FIGS. 13 and 14. The following description will be based on differences from the semiconductor device shown in FIGS. 1 to 3.

FIG. 13 is a view illustrating a semiconductor device according to some other example embodiments of the present disclosure. FIG. 14 is an enlarged view illustrating a region R4 of FIG. 13.

Referring to FIGS. 13 and 14, in the semiconductor device according to some other embodiments of the present disclosure, a via filling layer 350 may completely fill the inside of the via trench T2.

For example, an upper wiring pattern 370 may include a first upper wiring barrier layer 171, an interface layer 372, a second upper wiring barrier layer 373 and an upper wiring filling layer 374. For example, an upper surface 350a of the via filling layer 350 may be more protruded to be convex in the vertical direction DR2 than the upper surface 140a of the second interlayer insulating layer 140. For example, the interface layer 372 disposed between the upper surface 350a of the via filling layer 350 and the second upper wiring barrier layer 373 is not disposed inside the via trench T2. In addition, each of the second upper wiring barrier layer 373 and the upper wiring filling layer 374 is not disposed inside the via trench T2. For example, at least a portion of the interface layer 372 disposed between the upper surface 350a of the via filling layer 350 and the second upper wiring barrier layer 373 may be in contact with the upper surface 140a of the second interlayer insulating layer 140.

The via filling layer 350, the interface layer 372, the second upper wiring barrier layer 373, and the upper wiring filling layer 374 may be formed of or include the same materials as those of the via filling layer 150, the interface layer 172, the second upper wiring barrier layer 173, and the upper wiring filling layer 174, respectively.

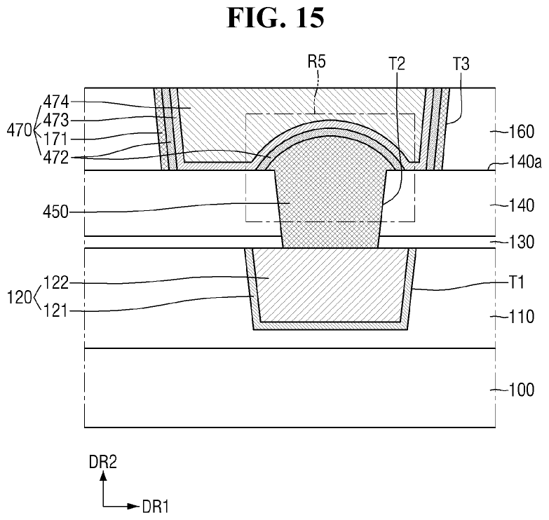

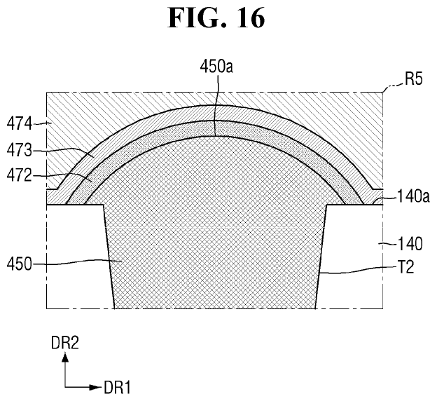

Hereinafter, a semiconductor device according to some other example embodiments of the present disclosure will be described with reference to FIGS. 15 and 16. The following description will be based on differences from the semiconductor device shown in FIGS. 1 to 3.

FIG. 15 is a view illustrating a semiconductor device according to some other example embodiments of the present disclosure. FIG. 16 is an enlarged view illustrating a region R5 of FIG. 15.

Referring to FIGS. 15 and 16, in the semiconductor device according to some other embodiments of the present disclosure, at least a portion of a via filling layer 450 may be in contact with the upper surface 140a of the second interlayer insulating layer 140.

For example, an upper wiring pattern 470 may include a first upper wiring barrier layer 171, an interface layer 472, a second upper wiring barrier layer 473 and an upper wiring filling layer 474. For example, the via filling layer 450 may completely fill the inside of the via trench T2. For example, an upper surface 450a of the via filling layer 450 may be more protruded to be convex in the vertical direction DR2 than the upper surface 140a of the second interlayer insulating layer 140. At least a portion of the via filling layer 450 may be in contact with the upper surface 140a of the second interlayer insulating layer 140 adjacent to the via trench T2.

For example, the interface layer 472 disposed between the upper surface 450a of the via filling layer 450 and the second upper wiring barrier layer 473 is not disposed inside the via trench T2. In addition, each of the second upper wiring barrier layer 473 and the upper wiring filling layer 474 is not disposed inside the via trench T2. For example, at least a portion of the interface layer 472 disposed between the upper surface 450a of the via filling layer 450 and the second upper wiring barrier layer 473 may be in contact with the upper surface 140a of the second interlayer insulating layer 140.

The via filling layer 450, the interface layer 472, the second upper wiring barrier layer 473, and the upper wiring filling layer 474 may be formed of or include the same materials as those of the via filling layer 150, the interface layer 172, the second upper wiring barrier layer 173, and the upper wiring filling layer 174, respectively.

Although the embodiments according to the present disclosure have been described with reference to the accompanying drawings, it will be apparent to those skilled in the art that the present disclosure can be fabricated in various forms without being limited to the above-described embodiments and can be embodied in other specific forms without departing from technical spirits and essential characteristics of the present disclosure. Thus, the above embodiments are to be considered in all respects as illustrative and not restrictive.

What is claimed is:

1. A semiconductor device comprising:
a substrate;
a first interlayer insulating layer disposed on the substrate;
a lower wiring pattern disposed in the first interlayer insulating layer;
a second interlayer insulating layer disposed on the first interlayer insulating layer;
a via trench formed in the second interlayer insulating layer, the via trench extending to an upper surface of the lower wiring pattern;
a via filling layer filling the via trench;
a third interlayer insulating layer in contact with an upper surface of the second interlayer insulating layer on the second interlayer insulating layer, the third interlayer insulating layer including a material different from a material included in the second interlayer insulating layer;
an upper wiring trench formed on the via trench in the third interlayer insulating layer; and
an upper wiring pattern in contact with an upper surface of the via filling layer, the upper wiring pattern filling the upper wiring trench, the upper wiring pattern including a first upper wiring barrier layer disposed on sidewalls of the upper wiring trench, a second upper wiring barrier layer disposed on sidewalls of the first upper wiring barrier layer and the upper surface of the via filling layer, and an upper wiring filling layer disposed on the second upper wiring barrier layer,
wherein the via filling layer and the first upper wiring barrier layer include the same material.

2. The semiconductor device of claim 1, wherein at least a portion of the second upper wiring barrier layer is in contact with the upper surface of the second interlayer insulating layer in the upper wiring trench.

3. The semiconductor device of claim 1, wherein the first upper wiring barrier layer is not disposed between the upper surface of the second interlayer insulating layer and the upper wiring filling layer and between the upper surface of the via filling layer and the upper wiring filling layer.

4. The semiconductor device of claim 1, further comprising an interface layer disposed between the first upper wiring barrier layer and the second upper wiring barrier layer and between the upper surface of the via filling layer and the second upper wiring barrier layer.

5. The semiconductor device of claim 4, wherein at least a portion of the interface layer is in contact with sidewalls of the second interlayer insulating layer in the via trench.

6. The semiconductor device of claim 4, wherein at least a portion of the interface layer disposed on the upper surface of the via filling layer is in contact with the upper surface of the second interlayer insulating layer.

7. The semiconductor device of claim 1, wherein each of the via filling layer and the first upper wiring barrier layer includes any one of molybdenum (Mo) and ruthenium (Ru).

8. The semiconductor device of claim 1, wherein the second interlayer insulating layer includes tetraethyl orthosilicate (TEOS), and the third interlayer insulating layer includes a low dielectric constant material different from tetraethyl orthosilicate (TEOS).

9. The semiconductor device of claim 1, wherein at least a portion of the upper surface of the via filling layer is formed to be higher than the upper surface of the second interlayer insulating layer.

10. The semiconductor device of claim 9, wherein at least another portion of the upper surface of the via filling layer is formed to be lower than the upper surface of the second interlayer insulating layer.

11. The semiconductor device of claim 1, wherein at least a portion of the second upper wiring barrier layer is in contact with sidewalls of the second interlayer insulating layer in the via trench.

12. The semiconductor device of claim 1, wherein at least a portion of the via filling layer is in contact with the upper surface of the second interlayer insulating layer.

13. A semiconductor device comprising:
a substrate;
a first interlayer insulating layer disposed on the substrate;
a via trench formed in the first interlayer insulating layer;
a via filling layer filling the via trench;
a second interlayer insulating layer in contact with an upper surface of the first interlayer insulating layer on the first interlayer insulating layer, the second interlayer insulating layer including a material different from a material included in the first interlayer insulating layer;
an upper wiring trench formed on the via trench in the second interlayer insulating layer; and
an upper wiring pattern in contact with an upper surface of the via filling layer, the upper wiring pattern filling the upper wiring trench, the upper wiring pattern including a first upper wiring barrier layer disposed on sidewalls of the upper wiring trench, a second upper wiring barrier layer disposed on sidewalls of the first upper wiring barrier layer and the upper surface of the via filling layer, an upper wiring filling layer disposed on the second upper wiring barrier layer, and an interface layer disposed between the first upper wiring barrier layer and the second upper wiring barrier layer and between the upper surface of the via filling layer and the second upper wiring barrier layer,
wherein the via filling layer and the first upper wiring barrier layer include the same material.

14. The semiconductor device of claim 13, wherein at least a portion of the second upper wiring barrier layer is in contact with the upper surface of the first interlayer insulating layer in the upper wiring trench.

15. The semiconductor device of claim 13, wherein each of the via filling layer and the first upper wiring barrier layer includes any one of molybdenum (Mo) and ruthenium (Ru).

16. The semiconductor device of claim 13, wherein at least a portion of the interface layer is in contact with sidewalls of the second interlayer insulating layer in the via trench.

17. The semiconductor device of claim 13, wherein at least a portion of the interface layer disposed on the upper surface of the via filling layer is in contact with an upper surface of the second interlayer insulating layer.

18. The semiconductor device of claim 13, wherein at least a portion of the second upper wiring barrier layer is in contact with sidewalls of the second interlayer insulating layer in the via trench.

19. The semiconductor device of claim 13, wherein the upper surface of the via filling layer is formed to be entirely lower than the upper surface of the first interlayer insulating layer.

20. A semiconductor device comprising:
a substrate;
a first interlayer insulating layer disposed on the substrate;
a lower wiring pattern disposed in the first interlayer insulating layer;
a second interlayer insulating layer disposed on the first interlayer insulating layer, the second interlayer insulating layer including tetraethyl orthosilicate (TEOS);
a via trench formed in the second interlayer insulating layer, the via trench extending to an upper surface of the lower wiring pattern;
a via filling layer filling the via trench;
a third interlayer insulating layer in contact with an upper surface of the second interlayer insulating layer on the second interlayer insulating layer, the third interlayer insulating layer including a low dielectric constant material different from tetraethyl orthosilicate (TEOS);
an upper wiring trench formed on the via trench in the third interlayer insulating layer; and
an upper wiring pattern in contact with an upper surface of the via filling layer, the upper wiring pattern filling the upper wiring trench, the upper wiring pattern including a first upper wiring barrier layer disposed on sidewalls of the upper wiring trench, a second upper wiring barrier layer disposed on sidewalls of the first upper wiring barrier layer and the upper surface of the via filling layer, an upper wiring filling layer disposed on the second upper wiring barrier layer, and an interface layer disposed between the first upper wiring barrier layer and the second upper wiring barrier layer and between the upper surface of the via filling layer and the second upper wiring barrier layer,
wherein each of the via filling layer and the first upper wiring barrier layer includes molybdenum (Mo),
wherein at least a portion of the second upper wiring barrier layer is in contact with the upper surface of the second interlayer insulating layer in the upper wiring trench, and
wherein at least a portion of the upper surface of the via filling layer is formed to be higher than the upper surface of the second interlayer insulating layer.
